(19) United States
(12) Patent Application Publication
(10) Pub. No.: US 2015/0184301 A1
(43) Pub. Date: Jul. 2, 2015

(54) SUBSTRATE PROCESSING APPARATUS AND METHOD OF MANUFACTURING SEMICONDUCTOR DEVICE

(71) Applicant: Hitachi Kokusai Electric Inc., Tokyo (JP)

(72) Inventor: Shuhei SAIDO, Toyama-shi (JP)

(73) Assignee: Hitachi Kokusai Electric Inc., Tokyo (JP)

(21) Appl. No.: 14/581,492

(22) Filed: Dec. 23, 2014

(30) Foreign Application Priority Data
Dec. 27, 2013 (JP) 2013-270651

(51) Int. Cl. C23C 16/52; C23C 16/455; C23C 16/46

(52) U.S. Cl. CPC C23C 16/52; C23C 16/46; C23C 16/4557

(57) ABSTRACT

Provided is a substrate processing apparatus capable of suppressing the difference between temperatures of a susceptor and the shower head. The substrate processing apparatus includes a process chamber configured to process a substrate; a substrate placement device disposed in the process chamber, the substrate placement device comprising a substrate placement surface where the substrate is placed and a first heater; a shower head disposed opposite to the substrate placement surface, the shower head comprising a second heater and an opposing surface facing the substrate placement surface; a processing gas supply system configured to supply a processing gas for processing the substrate placed on the substrate placement surface into the process chamber via the shower head; an exhaust system configured to evacuate an inner atmosphere of the process chamber; and a controller configured to control outputs of the first heater and the second heater.

### CROSS-REFERENCE TO RELATED PATENT APPLICATION

This U.S. non-provisional patent application claims priority under 35 U.S.C. §119 of Japanese Patent Application No. 2013-270651, filed an Dec. 27, 2013, in the Japanese Patent Office, the entire contents of which are hereby incorporated by reference.

### BACKGROUND OF THE INVENTION

1. Field of the Invention

The present invention relates to a semiconductor device manufacturing method including a substrate processing process, and a substrate processing apparatus capable of performing a process included in the semiconductor device manufacturing method.

2. Description of the Related Art

Recently, there has been a tendency to manufacture semiconductor devices, such as flash memories, in a highly integrated manner. Thus, pattern sizes of semiconductor devices are becoming finer and finer. To form such a fine pattern, a process of performing a predetermined treatment such as oxidation or nitridation may be performed on a substrate as a process included in a semiconductor device manufacturing process. To perform the predetermined treatment, a substrate processing apparatus forms a Mm on or performs a surface treatment on the substrate by supplying a processing gas to the substrate.

A single-wafer type substrate processing apparatus that supplies a gas through an upper portion of a substrate, for example, using a shower head has been known as an example of a substrate processing apparatus according to the related art. In the single-wafer type substrate processing apparatus, a substrate is heated in a process chamber using a heating mechanism of a susceptor and, for example, a film-forming gas is supplied to a surface of the substrate via a shower head through a gas supply line connected to the process chamber. When the film-forming gas flowing on the substrate causes a chemical reaction to occur due to heat energy, a thin film is formed on the substrate. In this case, two or more types of reactive gases may be alternately supplied to the substrate so as to form one of layers of a film at a time.

When the substrate is heated by the heating mechanism of the susceptor, a thermal difference occurs between the susceptor and the shower head. When the thermal difference occurs between the susceptor and the shower head, it is difficult to maintain the substrate at a uniform temperature. Also, when the temperature of the shower head is lower than that of the susceptor, a processing gas is likely to be supplied to the substrate without being sufficiently heated, which decreases the performance of a process.

Also, although a temperature of the susceptor may be maintained at a substrate processing temperature by monitoring the temperature of the susceptor, a film is attached to the shower head to change the emissivity of a surface of the shower head when substrate processing is repeatedly performed. As a result, the temperature of the shower head changes and thus the temperature of the substrate may change.

### SUMMARY OF THE INVENTION

It is an object of the present invention to provide a substrate processing apparatus using a shower head, in which the difference between temperatures of a susceptor serving as a substrate placement device and the shower head can be controlled to be within a predetermined range.

According to one aspect of the present invention, there is provided a substrate processing apparatus including a process chamber configured to process a substrate; a substrate placement device disposed in the process chamber, the substrate placement device comprising a substrate placement surface where the substrate is placed and a first heater; a shower head disposed opposite to the substrate placement surface, the shower head comprising a second heater and an opposing surface facing the substrate placement surface; a processing gas supply system configured to supply a processing gas for processing the substrate placed on the substrate placement surface into the process chamber via the shower head; an exhaust system configured to evacuate an inner atmosphere of the process chamber; and a controller configured to control outputs of the first heater and the second heater such that the substrate placement device is at a predetermined temperature and a difference between temperatures of the opposing surface and the substrate placement device is within a predetermined range when the processing gas is supplied by the processing gas supply system after the substrate is placed on the substrate placement surface.

According to another aspect of the present invention, there is provided a method of manufacturing a semiconductor device, including (a) placing a substrate on a substrate placement surface of a substrate placement device comprising a first heater; (b) supplying to the substrate placed on the substrate placement surface a processing gas for processing the substrate via a shower head comprising a second heater and an opposing surface facing the substrate placement surface; and (c) controlling an output of the first heater such that the substrate placement device is at a predetermined temperature and an output of the second heater such that a difference between temperatures of the opposing surface and the substrate placement device is within a predetermined range when the processing gas is being supplied in the step (b).

### BRIEF DESCRIPTION OF THE DRAWINGS

FIG. 1 is a schematic longitudinal cross-sectional view of a substrate processing apparatus according to an embodiment of the present invention;

FIG. 2 is a flowchart of a substrate processing process according to an embodiment of the present invention; and

FIG. 3 is a sequence diagram of a film-forming process according to an embodiment of the present invention.

### DETAILED DESCRIPTION OF THE PREFERRED EMBODIMENTS

(1) Structure of Substrate Processing Apparatus

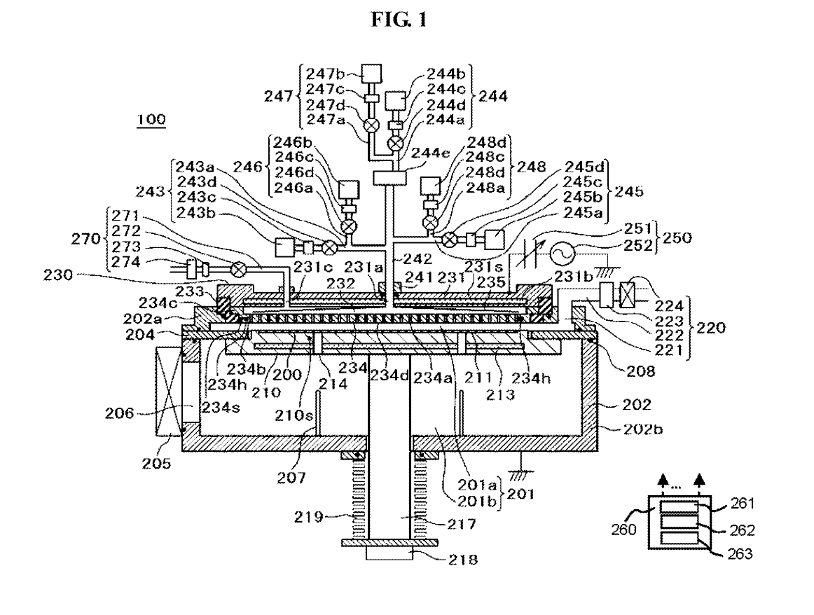

First, a substrate processing apparatus (hereinafter, also referred to simply as an ‘apparatus’) 100 according to an embodiment of the present invention will be described with reference to FIG. 1. FIG 1 is a schematic longitudinal (vertical) cross-sectional view of the substrate processing apparatus 100 according to an embodiment of the present invention. The substrate processing apparatus 100 is an apparatus that forms a thin film, and is configured as a single-wafer type substrate processing apparatus capable of processing one or several substrates as illustrated in FIG. 1.

As illustrated in FIG. 1, the substrate processing apparatus 100 includes a process container 202. The process container 202 is configured, for example, as a flat cylindrical airtight container having a circular cross-section (horizontal section). Also, sidewalls or a lower wall of the process container 202 is formed of a metal material, e.g., aluminum (Al) or stainless steel (steel-use-stainless (SUS)).

In the process container 202, a process chamber 201 is formed to process a wafer 200, e.g., a silicon wafer, as a substrate. The process chamber 201 includes a process space 201a for processing the wafer 200, and a transfer space 201b for transferring the wafer 200. The exterior of the process container 202 is formed by an upper container 202a, a lower container 202b and a shower head 230 which is a ceiling portion. A partition plate 204 is installed between the upper container 202a and the lower container 202b to separate the process space 201a and the transfer space 201b from each other.

The process space 201a is a space surrounded by the upper container 202a, the shower head 230, and a substrate placement device 210 (which will be described below) and located above the partition plate 204. The transfer space 201b is a space surrounded by the lower container 202b and the substrate placement device 210, and located below the partition plate 204. An O-ring 208 is installed between (or at an interface between) the upper container 202a and partition plate 204 and between (or at an interface between) the partition plate 204 to air-tightly close the inside of the process container 202.

At a side of the lower container 202b, a substrate loading exit 206 is installed adjacent to a gate valve 205. The water 200 is moved between adjacent substrate transfer chambers (not shown) via the substrate loading exit 206. A plurality of lift pins 207 are vertically installed on a bottom portion of the lower container 202b. The lower container 202b is electrically grounded.

The substrate placement device 210 supporting the wafer 200 is disposed between the process space 201a and the transfer space 201b. The substrate placement device 210 is formed of, for example, a non-metal material such as aluminum nitride (AlN), a ceramic, quartz, etc. The substrate placement device 210 includes a substrate placement surface 211 on which the water 200 is placed, a substrate placement device heater 213 which is a heating source included in the substrate placement device 210 to heat the wafer 200, and a substrate placement device temperature sensor 210s that senses a temperature of the substrate placement device 210. The substrate placement device heater 213 is configured as, for example, a resistive heater. A controller 260 which will be described below is configured to control the substrate placement device 210 to a predetermined temperature, based on the temperature sensed by the temperature sensor 210s.

The substrate placement surface 211 is disposed in the process space 201a. In the substrate placement device 210, substrate placement device through-holes 214 through which the lilt pins 207 pass are installed in locations corresponding to the lift pins 207.

The substrate placement device 210 is supported by a shaft 217. The shaft 217 passes through a bottom portion of the process container 202 and is connected to a lifting mechanism 218 outside the process container 202. By operating the lifting mechanism 218 to lift the shaft 217 and the substrate placement device 210, the wafer 200 placed on the substrate placement surface 211 may be moved upward. Also, the circumference of a lower end portion of the shaft 217 is covered with a bellows 219 and thus the inside of the process container 202 is maintained in an air-tight state.

The substrate placement device 210 is moved downward to move the substrate placement surface 211 to the substrate loading exit 206 (i.e., a wafer transfer position) so as to transfer the wafer 200, and is moved upward to move the wafer 200 to a processing position (i.e., a wafer processing position) so as to process the wafer 200 as illustrated in FIG. 1.

In detail, when the substrate placement device 210 is moved downward to the wafer transfer position, upper end portions of the lift pins 207 protrude from an upper surface of the substrate placement surface 211 to support the wafer 200 with the lift pins 207 from below. When the substrate placement device 210 is moved upward to the wafer processing position, the lift pins 20 are buried downward from the upper surface of the substrate placement surface 211 so that the wafer 200 may be supported by the substrate placement surface 211 from below. Also, the lift pins 207 are preferably formed of, for example, quartz or alumina to directly contact the wafer 200.

(Gas Introduction Hole)

In an upper surface (a ceiling wall) of the shower head 230 (which will be described in detail below), a gas introduction hole 241 is disposed to supply various gases into the process chamber 201. The structure of a gas supply system connected to the gas introduction hole 241 will be described below.

(Shower Head)

The shower head 230, which is a ceiling portion of the process chamber 201, is installed on the process chamber 201. The gas introduction hole 241 is connected to a lid 231 of the shower head 230. The shower head 230 is a gas dispersion mechanism for dispersing a gas into the process chamber 201. The shower head 230 is installed between the gas introduction hole 241 and the process chamber 201 to communicate the gas introduction hole 241 and the process chamber 201 with each other.

The shower head 230 includes a dispersion plate 234 between the gas introduction hole 241 and the process space 201a to disperse a gas introduced via the gas introduction hole 241. A plurality of through-holes 234a are disposed in the dispersion plate 234. The through-holes 234a are disposed opposite the substrate placement surface 211. The dispersion plate 234 includes a convex part 234b having the through-holes 234a and a flange part 234c installed around the convex part. The flange part 234c is supported by an insulating block 233 which is an electrically insulating structure.

The dispersion plate 234 further includes a dispersion plate heater 234h, which is a heating device for heating the dispersion plate 234 (i.e., the shower head 230), and a temperature sensor 234s, which is a temperature detector for detecting a temperature of the dispersion plate 234. In the embodiment of FIG. 1, the dispersion plate heater 234h is installed on the flange part 234c which constitutes an outer circumference of the dispersion plate 234 such that a top view thereof has a round donut shape but is not limited thereto. For example, the dispersion plate heater 234h may also be installed between adjacent through-holes 234a. The dispersion plate heater 234h is configured as, for example, a resistive heater. The controller 260 which will be described below is configured to control the dispersion plate 234 to have a predetermined temperature, based on a temperature sensed by the temperature sensor 234s.

Also, the dispersion plate 234 is installed at a position opposite the substrate placement surface 211, and includes an opposing surface 234d facing the substrate placement surface 211 (i.e., the wafer 200).

A gas introduced via the gas introduction hole 241 is supplied into the buffer space in a buffer chamber 232 of the shower head 230 via a lid hole 231a disposed in the lid 231. In the shower head 230, a buffer chamber 232 is installed between the lid 231 and the dispersion plate 234 to disperse a gas introduced via the gas introduction hole 241 to all regions of a surface of the dispersion plate 234.

In the buffer chamber 232, a gas guide 235 is installed to form the flow of a gas supplied into the buffer chamber 232. The gas guide 235 communicates with the gas introduction hole 241, and has a conical shape as peak of which is the lid hole 231a. The diameter of the gas guide 235 increases from the lid hole 231a to dispersion plate 234, i.e., a downward direction. A horizontal diameter of a lower end of the gas guide 235 is greater than a diameter of an outermost circumferential, portion of a group of the plurality of through-holes 234a. Through the gas guide 235, a gas supplied into the buffer chamber 232 is dispersed to be more uniform.

Accordingly, a gas introduced via the gas introduction hole 241 is supplied into the buffer chamber 232 installed in the shower head 230 via the lid hole 231a disposed in the lid 231. Then, the gas is dispersed to be uniform through the dispersion plate 234 and the gas guide 235 and is then supplied into the process chamber 201 via the through-hole 234a of the dispersion plate 234.

The lid 231 of the shower head 230 is formed of a conductive metal, and is used as an electrode for generating plasma in the buffer chamber 232 or the process chamber 201. The insulating block 233 is installed between the lid 231 and the upper container 202a, and insulates between the lid 231 and the upper container 202a. Also, a lid heating device 231b that heats the lid 231 and a temperature sensor 231s which is a temperature detector that detects the temperature of the lid 231 are installed at the lid 231. The lid heating device 231b is configured as, for example, a resistive heater. The controller 260, which will be described in detail below, is configured to control the lid 231 to have a predetermined temperature, based on a temperature detected by the temperature sensor 231s.

A second exhaust system 270 (shower head exhaust line) is installed on the lid 231 above the buffer chamber 232 to discharge an atmosphere in the buffer chamber 232. The second exhaust system 270 will be described below.

(Gas Supply System)

A common gas supply pipe 242 is connected to the gas introduction hole 241 connected to the lid 231 of the shower head 230. A first gas supply pipe 243a, a second gas supply pipe 244a and a third gas supply pipe 245a are connected to the common gas supply pipe 242. The second gas supply pipe 244a is connected to she common gas supply pipe 242 via a remote plasma generator 244e.

A gas supply system includes a first gas supply system 243, a second gas supply system 244 and a third gas supply system 245, as will be described below. Each of the first gas supply system 243 and the second gas supply system 244 includes a processing gas supply system configured to supply a processing gas for processing a substrate. The third gas supply system 245 includes an inert gas supply system and a cleaning gas supply system 248.

A first-element-containing gas is mainly supplied via the first gas supply system 243 including the first gas supply pipe 243a. A second-element-containing gas is mainly supplied via the second gas supply system 244 including the second gas supply pipe 244a. Via the third gas supply system 245 including the third gas supply pipe 245a, an inert gas is mainly supplied when the wafer 200 is to be processed and a cleaning gas is mainly supplied when the shower head 230 or the process chamber 201 is to be cleaned.

(First Gas Supply System)

At the first gas supply pipe 243a, a first gas supply source 243b, a mass flow controller (MFC) 243c which is a flow rate controller (flow rate controller) and a valve 243d which is an opening/closing valve are sequentially installed from an upstream end with respect to flow of a gas.

A gas containing a first element (hereinafter referred to as the ‘first-element-containing gas’) is supplied into the shower head 230 through the first gas supply pipe 243a via the MFC 243c, the valve 243d and the common gas supply pipe 242.

The first-element-containing gas is a source gas, i.e., one of processing gases. Here, the first element is, for example, titanium (Ti). That is, the first-element-containing gas is, for example, a titanium-containing gas. For example, TiCl₄ (titanium tetrachloride) gas may be used as the titanium-containing gas. Also, the first-element-containing gas may have a solid, liquid, or gaseous state at normal temperature and pressure.

Also, a silicon-containing gas may be used as the first-element-containing gas. For example, organic silicon materials such as bis-tertiary butyl aminosilane (SiH₂ [NH(C₄H₉)]₂, abbreviated as ‘BTBAS’) gas, hexamethyldisilazane (C₆H₁₉NSi₂, abbreviated as ‘HMDS’), trisilylamine [(SiH₃)₃N, abbreviated as ‘TSA’], or the like may be used as the silicon-containing gas. These gases act as precursors.

A downstream end of a first inert gas supply pipe 246a is connected to the first gas supply pipe 243a downstream from the valve 243d. An inert gas supply source 246b, an MFC 246c which is a flow rate controller (flow rate controller) and a valve 246d which is an opening/closing valve are sequentially installed at the first inert gas supply pipe 246a from the upstream end.

An inert gas supplied through the first gas supply pipe 243a is, for example, nitrogen (N₂) gas. In addition to the N₂ gas, for example, a rare gas such as helium (He) gas, neon (Ne) gas, or argon (Ar) gas may be used as the inert gas.

An inert gas is supplied into the shower head 230 through the first inert gas supply pipe 246a via the MFC 246c, the valve 246d and the first gas supply pipe 243a. The inert gas acts as a carrier gas or a dilution gas in a film-forming process (S104) which will be described below.

The first-element-containing gas supply system 243 (which may also be referred to as a titanium-containing gas supply system) mainly includes the first gas supply pipe 243a, the MFC 243c and the valve 243d.

A first inert gas supply system 246 mainly includes the first inert gas supply pipe 246a, the MFC 246c and the valve 246d. The first inert gas supply system 246 may further include the inert gas supply source 246b and the first gas supply pipe 243a.

The first-element-containing gas supply system 243 may further include the first gas supply source 243b and the first inert gas supply system 246.

(Second Gas Supply System)

The remote plasma generator 244e is installed downstream from the second gas supply pipe 244a. A second gas supply source 244b, an MFC 244c which is a flow rate controller (How fate controller) and a valve 244d which is an opening/closing valve are sequentially installed at the second gas supply pipe 244a from the upstream end.

A gas containing a second element (hereinafter referred to as the ‘second-element-containing gas’) is supplied into the shower head 230 from the second gas supply pipe 244a via the MFC 244c, the valve 244d, the remote plasma generator 244e and the common gas supply pipe 242. The second-element-containing gas is changed into a plasma state by the remote plasma generator 244e and is then radiated onto the wafer 200.

The second-element-containing gas is one of the processing gases. Also, the second-element-containing gas may be considered as a reactive gas or a modifying gas.

Here, the second-element-containing gas contains the second element that is different from the first element. The second element is, for example, nitrogen (N). In the present embodiment, it is assumed that the second-element-containing gas is, for example, a nitrogen-containing gas. In detail, ammonia (NH₃) gas is used as the nitrogen-containing gas.

The second gas supply system 244 which is a second-element-containing gas supply system (which may also be referred to as a nitrogen-containing gas supply system) mainly includes the second gas supply pipe 244a, the MFC 244c and the valve 244d.

A downstream end of a second inert gas supply pipe 247a is connected to the second gas supply pipe 244a downstream from the valve 244d and upstream from the remote plasma generator 244e. An inert gas supply source 247b, an MFC 247c which is a flow rate controller (flow rate controller) and a valve 247d which is an opening/closing valve are sequentially installed at the second inert gas supply pipe 247a from, the upstream end.

An inert gas supplied through the second gas supply pipe 244a is, for example, nitrogen (N₂) gas. In addition to the N₂ gas, for example, a rare gas such as helium (He) gas, neon (Ne) gas, or argon (Ar) gas may be used as the inert gas.

An inert gas is supplied into the shower head 230 from the second inert gas supply pipe 247a via the MFC 247c, the valve 24d, the second gas supply pipe 244a and the remote plasma generator 244e. The inert gas acts as a carrier gas or a dilution gas in the film-forming process (S104) which will be described below.

A second inert gas supply system 247 mainly includes the second inert gas supply pipe 247a, the MFC 247c and the valve 247d. The second inert gas supply system 247 may further include the inert gas supply source 247b, the second gas supply pipe 244a and the remote plasma generator 244e.

The second gas supply system 244 may further include the second gas supply source 244b, the remote plasma generator 244e and the second inert gas supply system 247.

(Third Gas Supply System)

A third gas supply source 245b, an MFC 245c which is a flow rate controller (flow rate controller) and a valve 245d which is an opening/closing valve are sequentially installed at the third gas supply pipe 245a from the upstream end.

For example, an inert gas is supplied as a purge gas to the shower head 230 from the third gas supply source 245b via the MFC 245c, the valve 245d and the common gas supply pipe 242. The purge gas should be understood as a gas introduced into the process chamber 201 or the buffer chamber 232 to discharge an atmosphere (a gas) in the process chamber 201 or the buffer chamber 232.

The inert gas supplied from the third gas supply source 245b is, for example, nitrogen (N₂) gas. In addition to the N₂ gas, for example, a rare gas such as helium (He) gas, neon (Ne) gas or argon (Ar) gas may be used as the inert gas.

A downstream end of a cleaning gas supply pipe 248a is connected to the third gas supply pipe 245a downstream from the valve 245d. A cleaning gas supply source 248b, an MFC 248c which, is a flow rate controller (flow rate controller) and a valve 248d which is an opening/closing valve are sequentially installed at the cleaning gas supply pipe 248a from the upstream end.

The third, gas supply system 245 mainly includes the third gas supply pipe 245a, the MFC 245c and the valve 245d.

A cleaning gas supply system 248 mainly includes the cleaning gas supply pipe 248a, the MFC 248c and the valve 248d. The cleaning gas supply system 248 may further include the cleaning gas supply source 248b and the third gas supply pipe 245a.

The third gas supply system 245 may further include the third gas supply source 245b and the cleaning gas supply system 248.

In the substrate processing process, an inert gas is supplied into the shower head 230 from the third gas supply pipe 245a via the MFC 245c, the valve 245d and the common gas supply pipe 242. In a cleaning process, a cleaning gas is supplied into the shower head 230 via the MFC 248c, the valve 248d and the common gas supply pipe 242.

The inert gas supplied from the inert gas supply source 245b acts as a purge gas for purging a gas remaining in the process chamber 201 or the shower head 230 in the film-forming process (S104) which will be described below. Also, the inert gas may act as a carrier gas or a dilution gas of the cleaning gas in the cleaning process.

In the cleaning process, the cleaning gas supplied from the cleaning gas supply source 248b acts as a cleaning gas for removing byproducts and the like attached to the shower head 230 or the process chamber 201.

Here, the cleaning gas is, for example, nitrogen trifluoride (NF3) gas. For example, hydrofluoric acid (HF) gas, chlorine trifluoride (ClF3) gas, fluorine (F2) gas, or a combination thereof may be used as the cleaning gas.

(First Exhaust System)

An exhaust port 221 is installed on a side surface of an inner wall of the process chamber 201 (the upper container 202a) to exhaust an atmosphere in the process chamber 201. An exhaust pipe 222 is connected to the exhaust port 221. A pressure adjuster 223, such as an auto-pressure controller (APC), configured to control the inside of the process chamber 201 to have a predetermined pressure, and a vacuum pump 224 are connected in series to the exhaust pipe 222 according to the flow of a gas. A first exhaust system (process chamber exhaust line) 220 mainly includes the exhaust port 221, the exhaust pipe 222 and the pressure adjuster 223. The first exhaust system 220 may further include the vacuum pump 224.

(Second Exhaust System)

A shower head exhaust hole 231c is disposed to vertically pass through the lid 231 above the buffer chamber 232 so as to discharge an atmosphere in the buffer chamber 232. An exhaust pipe 271 is connected to the shower head exhaust hole 231c. A valve 237 configured to switch exhaust on/off, a pressure adjuster 237 (such as an APC) configured to control the inside of the buffer chamber 232 to have a predetermined pressure and a vacuum pump 274 are connected in series to the exhaust pipe 271 according to the flow of a gas. The second exhaust system (shower head exhaust line) 270 includes the exhaust pipe 271, the valve 272 and the pressure adjuster 273. The second exhaust system 270 may further include the vacuum pump 274.

Since the shower head exhaust hole 233c is located above the gas guide 235, a first half of a first purging process (S204) and a first half of a second purging process (S208) are set such that a gas flows as will be described below. That is, an inert gas supplied via the lid hole 231a is dispersed through the gas guide 235 to flow through the center and bottom of a space in the buffer chamber 232. Then, the inert gas circles at an end portion of the gas guide 235 and is then exhausted via the shower head, exhaust hole 231c.

An exhaust system includes the first exhaust system 220 and the second exhaust system 270. The second exhaust system 270 may be omitted according to a type of substrate processing, as will be described in detail below.

(Plasma Generation Device)

A high-frequency power source 252 is connected to the lid 231 of the shower head 230 via a matching device 251. Plasma is generated in the shower head 230 (particularly, the buffer chamber 232) and the process chamber 201 (particularly, the process space 201a) by adjusting impedance using the matching device 251 and supplying high-frequency power to the lid 231 from the high-frequency power source 252.

(Controller)

The substrate processing apparatus 100 includes a controller 260 which is a controller configured to control operations of various components of the substrate processing apparatus 100. The controller 260 includes at least an operation device 261 and a memory device 262. The operation device 261 calls a program or a control recipe for the substrate processing apparatus 100 from the memory device 262 according to a command received from the controller 260 or a user, and controls various components of the substrate processing apparatus 100 according to the program or the control recipe. The controller 260 may be configured as a dedicated computer or a general-purpose computer. For example, the controller 260 according to the present embodiment may be configured by preparing an external recording medium 263, such as an external memory device storing a program as described above, e.g., a magnetic disk (e.g., a magnetic tape, a flexible disk, a hard disk, etc.), an optical disc (e.g., a compact disc (CD), a digital versatile disc (DVD), etc.), a magneto-optical (MO) disc, or a semiconductor memory (e.g., a Universal Serial Bus (USB) memory, a memory card, etc.), and then installing the program in a general-purpose computer using the external recording medium 263. However, means for supplying a program to a computer are not limited to using the external recording medium 263. For example, a program may be supplied to a computer using communication means, e.g., the Internet or an exclusive line, without using the external recording medium 263. The memory device 262 or the external recording medium 263 may be configured as a non-transitory computer-readable recording medium. Hereinafter, the memory device 262 and the external recording medium 263 may also be referred to together simply as a ‘recording medium.’ When the term ‘recording medium’ is used in the present disclosure, it may be understood as only the memory device 262, only the external recording medium 263, or both the memory device 262 and the external recording medium 263.

(2) Substrate Processing Process

A substrate processing process of processing a substrate using the substrate processing apparatus 100 as a semiconductor manufacturing device will be briefly described below.

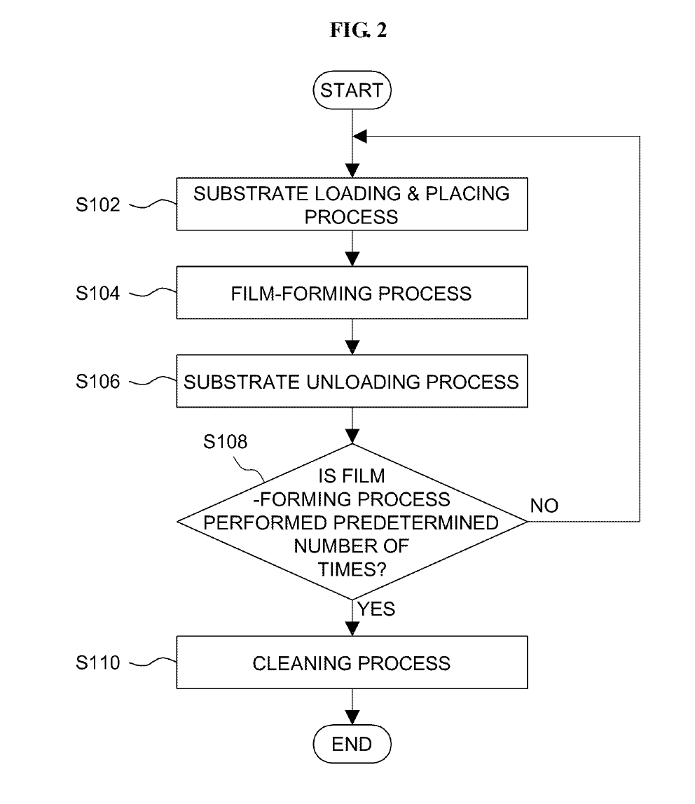

The substrate processing process is, for example, a process of manufacturing a semiconductor device. In the following description, operations or processing of various components of the substrate processing apparatus 100 are controlled by the controller 2601. FIG. 2 is a flowchart of a substrate processing process according to an embodiment of the present invention.

Here, a case in which a titanium nitride (TiN) film is formed as a thin film on the wafer 200 using titanium tetrachloride (TiCl₄) gas as a first-element-containing gas and ammonia (NH₃) gas as a second-element-containing gas will be described. Also, for example, a predetermined film may be formed on the wafer 200 beforehand. Also, a predetermined pattern may be formed on the wafer 200 or the predetermined film.

[Substrate Loading and Placing Process (S102)]

First, as illustrated in FIG 2, a substrate loading and placing process (S102) of loading the wafer 200 into the process chamber 201 and placing the wafer 200 on the substrate placement device 210 is performed. In detail, the substrate placement device 210 is moved downward to the wafer transfer position to cause the lift pins 207 to pass through the through-holes 214 of the substrate placement device 210. As a result, the lift pins 207 protrude by a predetermined height from a surface of the substrate placement device 210. Then, the gate valve 205 is opened, and the wafer 200 (a substrate to be processed) is loaded into the process chamber 201 using a wafer transfer machine (not shown) and transferred on the lilt pins 207. Thus, the wafer 200 is supported in a horizontal posture on the lift pins 207 protruding from the surface of the substrate placement device 210.

After the wafer 200 is loaded into the process container 202, the wafer transfer machine is withdrawn to the outside of the process container 202, the gate valve 205 is closed, and the inside of the process container 202 is air-tightly closed. Then, the wafer 200 is placed on the substrate placement surface 211 of the substrate placement device 210 by moving the substrate placement device 210 upward.

Also, when the wafer 200 is loaded into or unloaded from the process container 202, an inert gas, e.g., N₂ gas, is preferably supplied into the process container 202 from the inert gas supply system via the inert gas supply system while the inside of the process container 202 is exhausted using the first exhaust system 220. For example, the N₂ gas is preferably supplied into the process container 202 by opening at least the valve 245d of the third gas supply system 245 while the inside of the process container 202 is exhausted by operating the vacuum pump 224 to open the APC valve 223. Thus, particles may be suppressed from penetrating into the process container 202 or from being attached to the wafer 200 the via substrate loading exit 206.

The vacuum pump 224 of the first exhaust system 220 is constantly operated at least until the substrate loading and placing process (S102) to a substrate unloading process (S106) which will be described below end. In this ease, the exhausting of the inside of the process container 202 using the first exhaust system 220 and the supplying of the inert gas into the process container 202 using the third gas supply system 245 are continuously performed.

When the wafer 200 is placed on the substrate placement device 210, the substrate placement device 210, the dispersion plate 234 and the lid 231 of the shower head 230 are controlled to have a predetermined temperature. That is, when the wafer 200 is placed on the substrate placement device 210, the temperature of the substrate placement device 210 is controlled using the controller 260 by adjusting the amount of power to be supplied to the substrate placement device heater 213 based on temperature information detected by the substrate placement device temperature sensor 210s. The temperature of the dispersion plate 234 is controlled using the controller 260 by adjusting the amount of power to be supplied to the dispersion plate heater 234h based on temperature information detected by the dispersion plate temperature sensor 234s. The temperature of the shower head lid 231 is controlled using the controller 260 by adjusting the amount of power to be supplied to the lid heating device 231b based on temperature information detected by the shower head lid temperature sensor 231s.

Specifically, when the wafer 200 is placed on the substrate placement device 210, power is supplied to the heater 213 embedded in the substrate placement device 210 so as to control a surface of the wafer 200 to have a predetermined temperature. The temperature of the wafer 200 is, for example, in a range of room temperature to 500° C. or less, and preferably, in a range of 300° C. to 400° C. or less. Room temperature is 20° C.

The dispersion plate 234 (particularly, the opposing surface 234d) is controlled to have a predetermined temperature by supplying power to the dispersion plate heater 234h embedded in the dispersion plate 234. The temperature of the dispersion plate 234 may be controlled to be in a range of 300° C. to 400° C. or less and to be higher than a temperature at which byproducts are likely to be attached. In the present embodiment, since a main component of byproducts is ammonium chloride, the temperature of the dispersion plate 234 is controlled to be 150° C. or more.

A surface of the lid 231 is controlled to have a predetermined temperature by supplying power to the lid heating device 231b embedded in the lid 231. The surface of the lid 231 should be understood as a surface of the lid 231 opposite the gas guide 235. The temperature of the surface of the lid 231 is controlled to be, for example, in a range of 150° C. to 400° C., and preferably, to be higher than the temperature at which byproducts are likely to be attached.

In this case, the temperature of the dispersion plate 234 (i.e., the temperature of the shower head 230) is preferably increased to be higher than the temperature of the dispersion plate 234 when a film is formed so as to compensate for heat to be absorbed (which will be described below). Thus, even if heat of the dispersion plate 234 is absorbed by the wafer 200, the temperature of which is low, the temperature of the dispersion plate 234 may be prevented from being lower than or equal to the temperature at which byproducts are likely to be attached (i.e., a solidification temperature).

Also, in the film-forming process (S104), when the temperature of the dispersion plate 234 is lower than or equal to the temperature at which byproducts are likely to be attached, byproducts may be attached to the dispersion plate 234. When the byproducts peel off due to the flow of a gas, particles are generated. In the present embodiment, byproducts are ammonium chloride and the solidification temperature is about 150° C.

[Film Forming Process (S104)]

Next, the film-forming process (S104) is performed to form a thin film on a surface of the wafer 200. A basic flow of the film-formimg process (S104) will now be described, and the details of the film-forming process (S104) will be described with

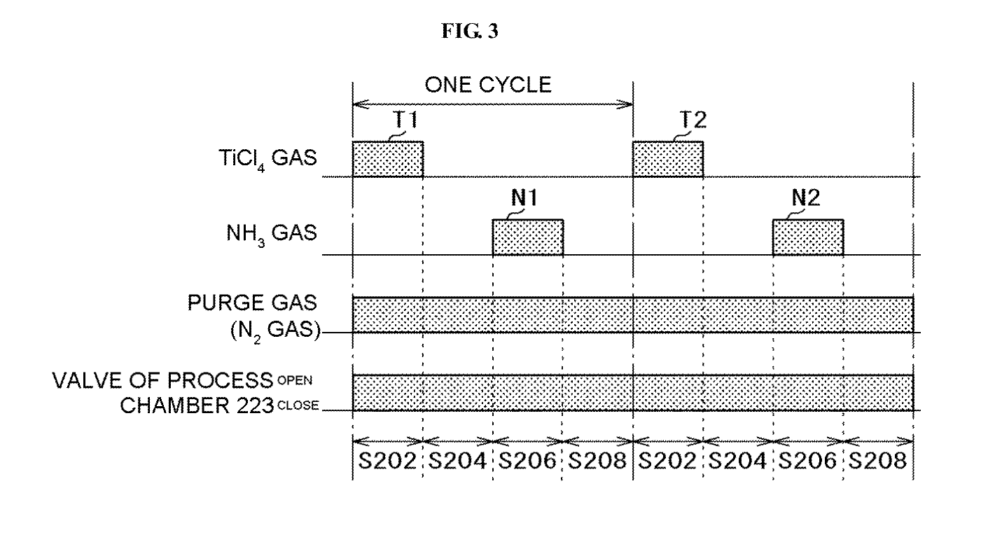

reference to FIG. 3 below.

In the film-forming process (S104), TiCl₄ gas is supplied into the process chamber 201 through the first gas supply system 243 via the buffer chamber 232 of the shower head 230. In this case, an inert gas is supplied through the third gas supply system 245 and exhausted through the first exhaust system 220 after the substrate loading and placing process (S102) is performed.

The supply of the TiCl₄ gas is stopped a predetermined time after the TiCl₄ gas is supplied. Then, the TiCl₄ gas is discharged from the process chamber 201 using a purge gas through the third gas supply system 245 at least via the first exhaust system 220.

After the TiCl₄ gas is discharged, ammonia (NH₃) gas that is in a plasma state is supplied into the process chamber 201 through the second gas supply system 244. The ammonia (NH₃) gas reacts with a titanium-containing film formed on the wafer 200 to form a titanium nitride film.

After a predetermined time passes, the supply of the ammonia (NH₃) gas is stopped. Then, the ammonia (NH₃) gas is discharged from the process chamber 201 using a purge gas through the third gas supply system 245 at least via the first exhaust system 220.

In the film-forming process (S104), a titanium nitride film is formed to a desired thickness by repeatedly performing the process described above. Also, in order to suppress byproducts from being deposited on an inner wall of the buffer chamber 232 during the film-forming process (S104), the buffer chamber 232 or the dispersion plate 234 is heated to a temperature higher than the temperature at which byproducts are likely to be attached, using the lid heating device 231b or the dispersion plate heater 234h.

Also, an inert gas is supplied through the third gas supply system 245 as described above when the TiCl₄ gas or the NH₃ gas is supplied in the film-forming process (S104) to facilitate the supply of the TiCl₄ gas or the NH₃ gas into the process chamber 201. However, the supplying of an inert gas through the third gas supply system 245 may be omitted according to the details of the substrate processing.

[Substrate Unloading Process (S106)]

Next, the wafer 200 on which the titanium nitride film is formed is unloaded from the process container 202. In detail, the substrate placement device 210 is moved downward to support the wafer 200 on the lift pins 207 protruding from the surface of the substrate placement device 210. Then, the gate valve 205 is opened while an inert gas is supplied into the process container 202 through the third gas supply system 245, and the wafer 200 is unloaded to the outside of the process container 202 using the wafer transfer machine. Then, in order to end the substrate processing process, the supply of the inert gas into the process container 202 from the third gas supply system 243 is stopped.

[Process (S108) of Determining a Number of Times the Film-Forming Process is Performed]

After the wafer 200 is unloaded, it is determined whether the number of times that the film-forming process (S104) is performed reaches a predetermined number of times. When it is determined that the number of times that the film-forming process (S104) is performed reaches the predetermined number of times, a cleaning process (S110) is performed. When it is determined that the number of times that the film-forming process (S104) is performed does not reach the predetermined number of times, the substrate loading and placing process (S102) is performed to start processing of a new wafer 200 that is on standby.

[Cleaning Process (S110)]

In a process (S108) of determining the number of times that the film-forming process (S104) is performed, when it is determined that the number of times that the film-forming process (S104) is performed reaches the predetermined number of times, the cleaning process (S110) is performed. In the cleaning process (S110), the substrate placement device 210 is located at the wafer processing position, and the cleaning gas is supplied into the process chamber 201 via the shower head 230 by opening the valve 248d of the cleaning gas supply system 248 while the wafer 200 is not on the substrate placement device 210.

After the insides of the shower bead 230 and the process chamber 201 are filled with the cleaning gas, plasma of the cleaning gas is generated in the shower head 230 (particularly, the buffer chamber 232) and the process chamber 201 (particularly, process space 201a) by performing impedance adjustment using the matching device 251 while supplying power to the shower head 230 from the high-frequency power source 252. The generated plasma of the cleaning gas removes byproducts attached to the inner walls of the shower head 230 and the process chamber 201.

Next, the film forming process (S104) will be described in detail with reference to FIG. 3 below. FIG 3 is a sequence diagram of a film-forming process according to an embodiment of the present invention. As illustrated in FIG. 3, the film-forming process (S104) includes a first processing gas supply process (S202), the first purging process (S204), a second processing gas supply process (S206) and the second purging process (S208).

As described above, in the film-forming process (S104) according to the present embodiment, an inert gas is also supplied into the process chamber 201 through the third gas supply system 245 while the TiCl₄ gas or the NH₃ gas is supplied. That is, as illustrated in FIG. 3, in the film-forming process (S104), an inert gas is continuously supplied into the process chamber 201 through the third gas supply system 245. In the film-forming process (S104), each of the temperatures of the substrate placement device 210, the dispersion plate 234 and the shower head lid 231 is set to be a predetermined temperature and maintained at the predetermined temperature.

The controller 260 controls the amount of power to be supplied to the substrate placement device heater 213 based on temperature information detected by the substrate placement device temperature sensor 210s, so that the temperature of the wafer 200 on the substrate placement device 210 may be equal to a predetermined temperature [i.e., the temperature of the wafer 200 in the film-forming process (S104)] which is, for example, in a range of room temperature to 500° C. or less (preferably, in a range of 300° C. to 400° C. or less). That is, an output of the substrate placement device heater 213 is controlled.

The controller 260 controls the amount of power to be supplied to the dispersion plate heater 234h based on temperature information detected by the dispersion plate temperature sensor 234s, so that the opposing surface 234d of the dispersion plate 234 may have, for example, a predetermined temperature that is in a range of 150° C. to 400° C. or less and that is greater than the temperature at which byproducts are likely to be attached. That is, an output of the dispersion plate heater 234h is controlled. Also, the temperature of the dispersion plate 234 is substantially the same as that of the wafer 200 in the film-forming process (S104), and may be greater than or less than the temperature of the wafer 200 as will be described below.

The controller 260 controls the amount of power to be supplied to the lid heating device 231b based on temperature information detected by the shower head lid temperature sensor 231s, so that a surface temperature of the lid 231 of the shower head lid 231 may be equal to a predetermined temperature that is, for example, in a range of 150° C. to 400° C. or less and that is greater than the temperature at which byproducts are likely to be attached. That is, an output of the lid heating device 231b is controlled.

Thus, in the first processing gas supply process (S202), the temperatures of the substrate placement device 210, the dispersion plate 234 and the shower head lid 231 are set to be, for example, 400° C., 400° C. and 200° C., respectively.

In this case, the controller 260 controls the difference between the temperature of the substrate placement device 210 and the temperature of the dispersion plate 234 (particularly, the temperature of the opposing surface 234d) to be in a predetermined range (e.g., 20° C. or less). Thus, the temperature of the wafer 200 is almost uniform within a plane of the wafer 200. As a result, the wafer 200 may be almost uniformly processed. When a film is formed, the film may be formed to an almost uniform thickness within the plane of the wafer 200.

The controller 260 preferably controls the temperature of the substrate placement device 210 to be substantially the same as that of the dispersion plate 234 (particularly, the opposing surface 234d). Thus, the temperature of the wafer 200 may be more uniform within the plane thereof and the wafer 200 may thus be more uniformly processed. “Substantially the same” should be understood as a range of temperature at which the wafer 200 may be Uniformly processed.

In this case, after the controller 260 preferably controls the substrate placement device 210 to have a preset temperature, it controls the dispersion plate 234 (particularly, the opposing surface 234d) to have a preset temperature. Because the temperature of the substrate placement device has major effect for increasing the temperature of the substrate placement device, the temperature of the wafer 200 may be rapidly stabilized.

In this ease, the controller 260 preferably controls the temperature of the dispersion plate 234 (particularly, the temperature of the opposing surface 234d) using a processing gas to be greater than a temperature at which byproducts are attached to the opposing surface 234d. Thus, byproducts may be prevented from being attached to the opposing surface 234d.

[First Processing Gas Supply Process (S202)]

After the setting of the temperatures is completed, in the first processing gas supply process (S202), the valve 243d of the first gas supply system 243 is opened to start supply of TiCl₄ gas as a first processing gas into the process chamber 201 via the gas introduction hole 241, the buffer chamber 232 and the through-holes 234a of the dispersion plate 234. In this case, the TiCl₄ gas is exhausted through the first exhaust system 220 while an inert gas is supplied into the process chamber 201 through the third gas supply system 245.

In the buffer chamber 232, the TiCl₄ gas is uniformly dispersed through the gas guide 235. The uniformly dispersed TiCl₄ gas is uniformly supplied to the wafer 200 in the process chamber 201 via the through-holes 234a.

In the first processing gas supply process (S202), the MFC 243c is controlled to set a flow rate of the TiCl₄ gas to be equal to a predetermined flow rate. The supply flow rate of the TiCl₄ gas is, for example, equal to or greater than 100 sccm and less than or equal to 5,000 sccm. Also, N₂ gas may be supplied as a carrier gas into the process chamber 201 through the first inert gas supply system 246, together with the TiCl₄ gas. Also, the degree of openness of the APC valve 223 of the first exhaust system 220 may be appropriately adjusted to control a pressure in the process container 202 to be equal to a predetermined pressure, e.g., 400 Pa.

In the process chamber 201, the TiCl₄ gas is supplied to the wafer 200 for a predetermined time, e.g., for 0.05 to 1 second. A titanium-containing layer is formed as a first-element-containing layer on a surface of the wafer 200 when the TiCl₄ gas comes in contact with the surface of the water 200.

The titanium-containing layer is formed to a predetermined thickness and in a predetermined distribution, based on, for example, the pressure in the process container 202, the flow rate of the TiCl₄ gas, the temperature of the substrate placement device 210 (susceptor) and the duration of a treatment performed in the process chamber 201, etc.

After a predetermined time passes, the valve 243d is closed and the supply of the TiCl₄ gas is stopped. However, the inert gas is continuously supplied through the third gas supply system 245 and exhausting is continuously performed through the first exhaust system 220.

[First Purging Process (S204)]

After the first processing gas supply process (S202), exhausting is continuously performed through the first exhaust system 220 and the purge gas (inert gas) is continuously supplied through the third gas supply system 245 to discharge an atmosphere in the process chamber 201, i.e., the TiCl₄ gas remaining in the process chamber 201. Also, the valve 272 is opened to adjust the degree of openness of the APC valve 273 or 223 to remove the TiCl₄ gas remaining in the shower head 230 (particularly, the buffer chamber 232) through the second exhaust system 270. With the use of the second exhaust system 270, a residual gas may be efficiently discharged from the buffer chamber 232.

The inert gas supplied in the first purging process (S204) removes a titanium component that has not combined with the wafer 200 in the first processing gas supply process (S202) from the wafer 200.

The valve 272 is closed a predetermined time after the performing of the first purging process (S204) starts, and the exhausting of the process chamber 201 through the second exhaust system 270 is stopped. As described above, when the predetermined time passes after the performing of the first purging process (S204) starts, the valve 272 is preferably closed to stop the exhausting performed through second exhaust system 270 while the exhausting is performed through the first exhaust system 220. Thus, the flow of the inert gas toward the first exhaust system 220 from the shower head 230 via the process chamber 201 is not influenced by the second exhaust system 270. Thus, the inert gas may be more reliably supplied to the wafer 200, thereby greatly increasing the efficiency of removing a residual gas from the wafer 200.

Also, when first purging process (S204) start, the exhausting performed through the second exhaust system 270 may be stopped. In this case, the TiCl₄ gas remaining in the process chamber 201 and the barter chamber 232 is discharged. Thus, it is easy to cause the inert gas to flow toward the first exhaust system 220 from the shower head 230 via the inside of the process chamber 201.

Alter the first purging process (S204) is performed for a predetermined time, the first purging process (S204) is ended and the second processing gas supply process (S206) is performed. However, the valve 245d is kept open and the purge gas is continuously supplied through the third gas supply system 245.

[Second Processing Gas Supply Process (S206)]

After the first purging process (S204), in the second processing gas supply process (S206), the valve 244d of the second gas supply system 244 is opened and supply of NH₃ gas as a second processing gas into the process chamber 201 via the remote plasma generator 244e, the gas introduction hole 241, the buffer chamber 232 and the through-holes 234a of the dispersion plate 234 is started while exhausting is performed through the first exhaust system 220. The NH₃ gas supplied into the process chamber 201 is changed into a plasma state through the remote plasma generator 244e. The NH₃ gas that is in the plasma state is supplied into the process chamber 201 via the buffer chamber 232 and the through-hole 234a, thereby uniformly supplying the NH₃ gas to the wafer 200. Accordingly, a film may be formed on the wafer 200 to a uniform thickness.

In this case, the MFC 244c is controlled to set the flow rate of the NH₃ gas to be equal to a predetermined flow rate. A supply flow rate of the NH₃ gas is, for example, in a range of 100 sccm to 5,000 sccm. Together with the NH₂ gas may be supplied as a carrier gas into the process chamber 201 through the second inert gas supply system 247. Also, the degree of openness of the APC valve 223 of the first exhaust system 220 is appropriately adjusted to set a pressure in the process container 202 to a predetermined pressure, e.g., 930 Pa.

The NH₃ gas that is in the plasma state is supplied to the wafer 200 in the process chamber 201 for a predetermined time, e.g., for 0.3 seconds. Then, the titanium-containing layer formed on the wafer 200 is modified by the plasma of the NH₃ gas to form a layer containing the element titanium and the element nitrogen on the wafer 200.

The layer containing the element titanium and the element nitrogen (a titanium-and-nitrogen-containing layer) is formed to have a predetermined thickness and distribution and an invasion depth of a predetermined nitrogen component or the like into the titanium-containing layer, based on, for example, the pressure in the process container 202, the How rate of the NH₃ gas, the temperature of the substrate placement device 210, the amount of power supplied to the plasma generation device 250, etc.

A titanium-and-nitrogen-containing layer is also formed on the dispersion plate 234 simultaneously with the formation, of the titanium-and-nitrogen-containing layer on the wafer 200. When the titanium-and-nitrogen-containing layer is formed on the opposing surface 234d of the dispersion plate 234, the emissivity when heat is radiated via the dispersion plate 234 is high. Since the emissivity is low, the controller 260 controls an output of the dispersion plate heater 234h to be high, thereby maintaining a quantity of heat radiated via the dispersion plate 234 at a constant level. In detail the controller 260 counts the number of times that the film-forming process (S104) is performed after the cleaning process (S110) is performed, and increases an output of the dispersion plate heater 234h according to the number of times that the film-forming process (S104) is performed. That is, the output of the dispersion plate heater 234h is controlled to be higher when the film-forming process (S104) is performed a greater number of times.

When a film formed on the opposing surface 234d of the dispersion plate 234 opposite the wafer 200 has a property of increasing the emissivity, the controller 260 controls the output of the dispersion plate heater 234h such that the output of the dispersion plate heater 234h is lower when the film-forming process (S104) is performed a greater number of times. Examples of such a film include a nitride film, an oxide film, etc.

As described above, while a processing gas is supplied into the process chamber 201, the controller 260 controls an output of the dispersion plate heater 234h when a film having a property of increasing the emissivity of heat radiated via the shower head 230 is attached to the opposing surface 234d to be lower than when the film is not attached to the opposing surface 234d, and controls the output of the dispersion plate heater 234h when a film having a property of decreasing the emissivity of heat radiated via the shower head 230 is attached to the opposing surface 234d to be higher than when the film is not attached to the opposing surface 234d.

The quantity of heat q (W/m2) transferred front the substrate placement device 210 to the dispersion plate 234 may be approximately expressed by Equation 1 below. In Equation 1, “σ” denotes an integer according to the Stefan-Boltzmann's law (≈5.67×10⁻⁸)(W/m²K⁴), “T1” denotes the temperature (K) of the substrate placement device 210, ‘T2” denotes the temperature (K) of the dispersion plate 234, “ε₁” denotes the emissivity of the substrate placement device 210, and “ε₂” denotes the emissivity of the dispersion plate 234.

$$q = σ ( {T}_{1}^{4} - {T}_{2}^{4} ) \frac{4}{\frac{1}{{ɛ}_{1}} + \frac{1}{{ɛ}_{2}} - 1} \qquad [ Equation 1 ]$$

As shown in Equation 1, when the temperature of the dispersion plate 234 is lower than that of the substrate placement device 210, heat is always transferred from the substrate placement device 210 to the dispersion plate 234. In this case, it is not easy to uniformly control the temperature of the wafer 200 within the plane thereof. Also, when a film-forming process is repeatedly performed, a film is attached to both the wafer 200 and a surface of the dispersion plate 234 (the opposing surface 234d), thereby changing the emissivity ε₂ of the surface of the dispersion plate 234. Furthermore, the emissivity ε₂ changes according to the thickness of a film as time elapses. In this case, as apparent from Equation 1, the quantity of transferred heat q also changes. That is, in order to continuously maintain the temperature of the wafer 200 constant, an output of the substrate placement device heater 213 needs to be controlled whenever the emissivity ε₂ changes.

In the present embodiment, when the temperatures of the dispersion plate 234 and the substrate placement device 210 are set to be the same, the transfer of heat is zero as indicated by Equation 1. Thus, even if a him is attached to the surface of the dispersion plate 234 (the opposing surface 234d) and the emissivity ε₂ of the surface of the dispersion plate 234 changes, the temperature of the dispersion plate 234 is not influenced.

Also, since temperatures of components above and below the wafer 200 (e.g., the temperature of the dispersion plate 234 and the temperature of the substrate placement device 210) become the same, it is easy to uniformly the temperature of the wafer 200 within the plane thereof, thereby improving the uniformity of the film-forming process.

After a predetermined time passes, the valve 244d is closed to stop the supply of the NH₃ gas into the process chamber 201. However, the inert gas is continuously supplied through the third gas supply system 245 and exhausting is continuously performed through the first exhaust system 220.

[Second Purging Process (S208)]

After the second processing gas supply process (S206), exhausting is continuously performed through the first exhaust system 220 and the purge gas (inert gas) is continuously supplied through the third gas supply system 245 to discharge an atmosphere in the process chamber 201, i.e., the NH₃ gas remaining in the process chamber 201. Also, the valve 272 is opened and the degree of openness of the APC valve 273 or 223 is controlled to remove the NH₃ gas remaining in the shower head 230 (particularly, the buffer chamber 232) through the second exhaust system 270.

The inert gas supplied in the second purging process (S208) removes a nitrogen component that has not combined with the wafer 200 in the second processing gas supply process (S206) from the wafer 200.

After a predetermined time passes after the second purging process (S208) is started, the valve 272 is closed to stop the exhausting performed through the second exhaust system 270. As described above, after the predetermined time passes after the second purging process (S208) is started, the valve 272 is preferably closed to stop the exhausting performed through the second exhaust system 270 while exhausting is performed through the first exhaust system 220. Thus, since the flow of the inert gas toward the first exhaust system 220 from the shower head 230 via the process chamber 201 is not influenced by the second exhaust system 270, the inert gas may be more reliably supplied to the wafer 200 and the efficiency of removing a residual gas from the wafer 200 may be greatly increased.

Otherwise, the exhausting performed through the second exhaust system 270 may be stopped (that is, use of the second exhaust system 270 is not needed) starting from a point in time at which the second purging process (S208) is started. Thus, the NH₃ gas remaining in the process chamber 201 and the buffer chamber 232 may be discharged. Thus, it is easy to form the flow of an inert gas toward the first exhaust system 220 from the shower head 230 via the process chamber 201.

After the second purging process (S208) is performed for a predetermined time, the second purging process (S208) is ended and the controller 260 determines whether a process cycle including, as one cycle, the first processing gas supply process (S202) to the second purging process (S208) is performed a predetermined number of times.

When the process cycle is not performed the predetermined number of times, the first processing gas supply process (S202) is performed and a process cycle including, as one cycle, the first processing gas supply process (S202), the first purging process (S204), the second processing gas supply process (S206) and the second purging process (S208) is performed. When the process cycle is performed a predetermined number of times, the film-forming process (S104) is ended,

(4) Effects of the Present Embodiment

According to the present embodiment, at least one among the following effects can be obtained.

(A1) When a processing gas is supplied, a substrate placement device is set to have a predetermined temperature and the difference between the temperatures of a shower head and the substrate placement device is set to be in a predetermined range, the temperature within a plane of a substrate can be easily improved in uniformity. Also, even if a flow rate of the processing gas is high, the processing gas can be sufficiently heated before it arrives at a substrate.

(A2) The temperature of a shower head when a surface is placed on a substrate placement surface is set to be higher than when the processing gas is supplied (i.e., when a film is farmed). Thus, the substrate can be easily controlled to have a predetermined temperature.

(A3) While the processing gas is supplied, an output of a shower head heater when a film having a property of increasing the emissivity of heat radiated from the shower head is attached to an opposing surface of the shower head facing the substrate placement device is set to be lower than when the film is not attached to the opposing surface. Thus, the difference between the temperatures of the shower head and the substrate placement device can be easily controlled to be in a predetermined range.

(A4) While the processing gas is supplied, an output of a shower head heater when a film having a property of decreasing the emissivity of heat radiated from the shower head is attached to the opposing surface of the shower head lacing the substrate placement device is set to be higher than when the film is not attached to the opposing surface. Thus, the difference between the temperatures of the shower head and the substrate placement device can be easily controlled to be in a predetermined range.

(A5) The temperature of the substrate can be more rapidly stabilized, since a heater is controlled to cause the shower head to have a predetermined temperature after the heater is controlled to cause the substrate placement device to have a predetermined temperature.

(A6) When the processing gas is supplied, the substrate placement device is set to have a predetermined temperature so as to equalize the temperatures of the shower head and the substrate placement device. Thus, the temperature of the substrate within the plane thereof can be uniformly improved very easily.

(A7) When the processing gas is supplied, the substrate placement device is set to have a predetermined temperature so that the temperature of the shower head may be controlled using the processing gas to be higher than a temperature at which byproducts are attached to an opposing surface, thereby suppressing byproducts from being attached to the opposing surface of the shower head.

<Other Embodiments of the Present Invention>

Although various embodiments of the present invention have been described above in detail, the present invention is not limited thereto and may be embodied in many different forms without departing from the scope of the invention.

Although a process of forming a titanium nitride (TiN) film on a substrate using a titanium-containing gas as a first-element-containing gas and a nitrogen-containing gas as a second-element-containing gas has been described in the previous embodiments, the present invention is not limited to the forming of the TiN film. For example, a hafnium (Hf)-containing gas, a zirconium (Zr)-containing gas, a titanium (Ti)-containing gas, or a silicon (Si)-containing gas may be used as the first-element-containing gas, and an oxygen-containing gas may be used as the second-element-containing gas. Also, the nitrogen-containing gas may be nitrogen (N₂) gas or the like.

The present invention is applicable to forming a high-k film, such as a hafnium oxide film (HfO film), a zirconium oxide film (ZrO film), a titanium oxide film (TiO film), or a silicon oxide film (SiO film), on a substrate.

Although a film is formed by alternately supplying two types of processing gases to a substrate in the previous embodiments, the present invention is not limited thereto and is applicable to forming a film by simultaneously supplying a plurality of types of processing gases to the substrate. Furthermore, the present invention is applicable to substrate processing other than the film-forming process.

Although the shower head 230 includes the shower head lid heating device 231b and the dispersion plate heater 234h as shower head heaters in the previous embodiments, a heating device may be installed in either the shower head lid 231 or the dispersion plate 234. In this case, in order to uniformize the temperature of the substrate, a heating device is preferably installed in the dispersion plate 234 closer to the wafer 200 (i.e., the substrate placement device 210). In order to greatly make the temperature of the substrate uniform, a heating device is preferably installed in both the shower head lid 231 and the dispersion plate 234.

Also, although the wafer 200 having a round shape is used as a substrate, a rectangular substrate may be used.

Due to the above structure, in a substrate processing apparatus using a shower head, the difference between temperatures of a susceptor serving as a substrate placement device and the shower head may be controlled to be within a predetermined range.

Exemplary embodiments of the present invention will be added herein.

(Supplementary Note 1)

According to one aspect of the present invention, there is provided a substrate processing apparatus including a process chamber configured to process a substrate; a substrate placement device disposed in the process chamber, the substrate placement device comprising a substrate placement surface where the substrate is placed and a first heater; a shower head disposed opposite to the substrate placement surface, the shower head comprising a second heater and an opposing surface facing the substrate placement surface; a processing gas supply system configured to supply a processing gas for processing the substrate placed on the substrate placement surface into the process chamber via the shower head; an exhaust system configured to evacuate an inner atmosphere of the process chamber; and a controller configured to control outputs of the first heater and the second heater such that the substrate placement device is at a predetermined temperature and a difference between temperatures of the opposing surface and the substrate placement device is within a predetermined range when the processing gas is supplied by the processing gas supply system after the substrate is placed on the substrate placement surface.

(Supplementary Note 2)

In the substrate processing apparatus of Supplementary note 1, the controller is configured to control the output of the second heater such that a temperature of the shower head when the substrate is placed on the substrate placement surface before supplying the processing gas into the process chamber is higher than that of the shower head when the processing gas is supplied into the process chamber by the processing gas supply system.

(Supplementary Note 3)

In the substrate processing apparatus of Supplementary note 1 or 2, the controller is configured to control the output of the second heater in a manner that the output of the second heater with a film attached to the opposing surface for increasing an emissivity of heat radiated from the shower head during a supply of the processing gas into the process chamber is lower than that of the second heater without the film attached to the opposing surface.

(Supplementary Note 4)

In the substrate processing apparatus of anyone of Supplementary notes 1 to 3, the controller is configured to control the output of the second heater in a manner that the output of the second heater with a film attached to the opposing surface for decreasing an emissivity of heat radiated from the shower head during a supply of the processing gas into the process chamber is higher than that of the second heater without the film attached to the opposing surface.

(Supplementary Note 5)

In the substrate processing apparatus of any one of Supplementary notes 1 to 4, the controller is configured to control the output of the second heater such that the temperature of the shower head reaches the predetermined temperature after controlling the output of the first heater such that the substrate placement device is at the predetermined temperature.

(Supplementary Note 6)

In the substrate processing apparatus of any one of Supplementary notes 1 to 5, the controller is configured to control the outputs of the first heater and the second heater such that the substrate placement device is at the predetermined temperature and the temperatures of the opposing surface and the substrate placement device are substantially equal when the processing gas is supplied by the processing gas supply system after the substrate is placed on the substrate placement surface.

(Supplementary Note 7)

In the substrate processing apparatus of any one of Supplementary notes 1 to 5, the controller is configured to control the outputs of the first heater and the second heater such that the substrate placement device is at the predetermined temperature and the temperature of the opposing surface is higher than a temperature whereat byproducts from the processing gas is attached to the opposing surface when the processing gas is supplied by the processing gas supply system after the substrate is placed on the substrate placement surface

(Supplementary Note 8)

According to another aspect of the present invention, there is provided a method of manufacturing a semiconductor device, including (a) placing a substrate on a substrate placement surface of a substrate placement device comprising a first heater; (b) supplying to the substrate placed on the substrate placement surface a processing gas for processing the substrate via a shower head comprising a second heater and an opposing surface facing the substrate placement surface; and (c) controlling an output of the first heater such that the substrate placement device is at a predetermined temperature and an output of the second heater such that a difference between temperatures of the opposing surface and the substrate placement device is within a predetermined range when the processing gas is being supplied in the step (b).

(Supplementary Note 9)

According to another aspect of the present invention, there is provided a method of manufacturing a semiconductor device, including (a) placing a substrate on a substrate placement surface of a substrate placement device including a first heater; (b) supplying a first-element-containing gas to the substrate placed on the substrate placement surface via a shower head including an opposing surface lacing the substrate placement surface and a second heater; and controlling outputs of the first and second heaters to adjust temperature of the substrate placement device to be equal to a predetermined temperature and to adjust the difference between temperatures of the opposing surface and the substrate placement device to be in a predetermined range; (c) removing a residue of the first-element-containing gas from the substrate placed on the substrate placement surface after the step (b); (d) after the step (c), supplying a second-element-containing gas to the substrate placed on the substrate placement surface via the shower head, and controlling outputs of the first and second heaters to adjust the temperature of the substrate placement device to be equal to a predetermined temperature and to adjust the difference between temperatures of the opposing surface and the substrate placement device to be in a predetermined range; and (e) removing a residue of the second-element-containing gas from the substrate placed on the substrate placement surface after the step (d), wherein the steps (h), (c), (d) and (e) are repeatedly performed.

What is claimed is:

1. A substrate processing apparatus comprising;
a process chamber configured to process a substrate;
a substrate placement device disposed in the process chamber, the substrate placement device comprising a substrate placement surface where the substrate is placed and a first heater;
a shower head disposed opposite to the substrate placement surface, the shower head comprising a second heater and an opposing surface facing the substrate placement surface;
a processing gas supply system configured to supply a processing gas for processing the substrate placed on the substrate placement surface into the process chamber via the shower head;
an exhaust system configured to evacuate an inner atmosphere of the process chamber; and
a controller configured to control outputs of the first heater and the second heater such that the substrate placement device is at a predetermined temperature and a difference between temperatures of the opposing surface and the substrate placement device is within a predetermined range when the processing gas is supplied by the processing gas supply system after the substrate is placed on the substrate placement surface.

2. The substrate processing apparatus of claim 1, wherein the controller is configured to control the output of the second heater such that a temperature of the shower head when the substrate is placed on the substrate placement surface before supplying the processing gas into the process chamber is higher than that of the shower head when the processing gas is supplied into the process chamber by the processing gas supply system.

3. The substrate processing apparatus of claim 2, wherein the controller is configured to control the output of the second heater in a manner that the output of the second heater with a film attached to the opposing surface for increasing an emissivity of heat radiated from the shower head during a supply of the processing gas into the process chamber is lower than that of the second heater without the film attached to the opposing surface.

4. The substrate processing apparatus of claim 3, wherein the controller is configured to control the output of the second heater such that the temperature of the shower head reaches the predetermined temperature after controlling the output of the first heater such that the substrate placement device is at the predetermined temperature.

5. The substrate processing apparatus of claim 1, wherein the controller is configured to control the output of the second heater in a manner that the output of the second heater with a film attached to the opposing surface for increasing an emissivity of heat radiated from the shower head during a supply of the processing gas into the process chamber is lower than that of the second heater without the film attached to the opposing surface.

6. The substrate processing apparatus of claim 5, wherein the controller is configured to control the output of the second heater such that the temperature of the shower head reaches the predetermined temperature after controlling the output of the first heater such that the substrate placement device is at the predetermined temperature.

7. The substrate processing apparatus of claim 5, wherein the controller is configured to control the outputs of the first heater and the second heater such that the substrate placement device is at the predetermined temperature and the temperatures of the opposing surface and the substrate placement device are substantially equal when the processing gas is supplied by the processing gas supply system after the substrate is placed on the substrate placement surface.

8. The substrate processing apparatus of claim 5, wherein the controller is configured to control the outputs of the first heater and the second heater such that the substrate placement device is at the predetermined temperature and the temperature of the opposing surface is higher than a temperature whereat byproducts from the processing gas is attached to the opposing surface when the processing gas is supplied by the processing gas supply system after the substrate is placed on the substrate placement surface.

9. The substrate processing apparatus of claim 1, wherein the controller is configured to control the output of the second heater in a manner that the output of the second heater with a film attached to the opposing surface for decreasing an emissivity of heat radiated from the shower head during a supply of the processing gas into the process chamber is higher than that of the second heater without the film attached to the opposing surface.

10. The substrate processing apparatus of claim 9, wherein the controller is configured to control the output of the second heater such that the temperature of the shower head reaches the predetermined temperature after controlling the output of the first heater such that the substrate placement device is at the predetermined temperature.

11. The substrate processing apparatus of claim 9, wherein the controller is configured to control the outputs of the first heater and the second heater such that the substrate placement device is at the predetermined temperature and the temperatures of the opposing surface and the substrate placement device are substantially equal when the processing gas is supplied by the processing gas supply system after the substrate is placed on the substrate placement surface.

12. The substrate processing apparatus of claim 9, wherein the controller is configured to control the outputs of the first heater and the second heater such that the substrate placement device is at the predetermined temperature and the temperature of the opposing surface is higher than a temperature whereat byproducts from the processing gas is attached to the opposing surface when the processing gas is supplied by the processing gas supply system after the substrate is placed on the substrate placement surface.

13. The substrate processing apparatus of claim 1, wherein the controller is configured to control the output of the second heater such that the temperature of the shower head reaches the predetermined temperature after controlling the output of the first heater such that the substrate placement device is at the predetermined temperature.

14. The substrate processing apparatus of claim 13, wherein the controller is configured to control the outputs of the first heater and the second heater such that the substrate placement device is at the predetermined temperature and the temperatures of the opposing surface and the substrate placement device are substantially equal when the processing gas is supplied by the processing gas supply system after the substrate is placed on the substrate placement surface.

15. The substrate processing apparatus of claim 13, wherein the controller is configured to control the outputs of the first heater and the second heater such that the substrate placement device is at the predetermined temperature and the temperature of the opposing surface is higher than a temperature whereat byproducts from the processing gas is attached to the opposing surface when the processing gas is supplied by the processing gas supply system after the substrate is placed on the substrate placement surface.

16. The substrate processing apparatus of claim 1, wherein the controller is configured to control the outputs of the first heater and the second heater such that the substrate placement device is at the predetermined temperature and the temperatures of the opposing surface and the substrate placement device are substantially equal when the processing gas is supplied by the processing gas supply system after the substrate is placed on the substrate placement surface.

17. The substrate processing apparatus of claim 1, wherein the controller is configured to control the outputs of the first heater and the second heater such that the substrate placement device is at the predetermined temperature and the temperature of the opposing surface is higher than a temperature whereat byproducts from the processing gas is attached to the opposing surface when the processing gas is supplied by the processing gas supply system after the substrate is placed on the substrate placement surface.

18. A non-transitory computer-readable recording medium causing a computer to perform;
(a) placing a substrate on a substrate placement surface of a substrate placement device comprising a first heater;
(b) supplying to the substrate placed on the substrate placement surface a processing gas for processing the substrate via a shower head comprising a second heater and an opposing surface facing the substrate placement surface; and
(c) controlling an output of the first heater such that the substrate placement device is at a predetermined temperature and an output of the second heater such that a difference between temperatures of the opposing surface and the substrate placement device is within a predetermined range when the processing gas is being supplied in the sequence (b).
